(19) United States
(12) Patent Application Publication
(10) Pub. No.: US 2020/0287522 A1
(43) Pub. Date: Sep. 10, 2020

(54) SURFACE ACOUSTIC WAVE FILTER AND DESIGN METHOD THEREOF

(71) Applicant: NIHON DEMPA KOGYO CO., LTD., Tokyo (JP)

(72) Inventor: RYUJI KAJIHARA, Saitama (JP)

(73) Assignee: NIHON DEMPA KOGYO CO., LTD., Tokyo (JP)

(21) Appl. No.: 16/808,381

(22) Filed: Mar. 4, 2020

(30) Foreign Application Priority Data
Mar. 5, 2019 (JP) 2019-039784

(51) Int. Cl. H03H 9/64; H03H 9/145; H03H 9/25; H03H 9/02; G06F 30/39

(52) U.S. Cl. CPC H03H 9/64; H03H 9/14544; G06F 30/39; H03H 9/02637; H03H 9/25

(57) ABSTRACT

A surface acoustic wave filter includes a longitudinal mode resonator type first filter portion, a longitudinal mode resonator type second filter portion, an input terminal, and an output terminal. Assuming a wavelength of a frequency propagating through the first filter portion is defined as λ, a distance between a center of a width of an electrode finger closest to the output side IDT electrode and a center of a width of an electrode finger closest to the input side IDT electrode is equal to or more than 0.57λ. The electrode finger closest to the output side IDT electrode is closest among electrode fingers that constitute the input side IDT electrode and are arranged in the propagation direction, and the electrode finger closest to the input side IDT electrode is closest among electrode fingers that constitute the output side IDT electrode and are arranged in the propagation direction.

### CROSS-REFERENCE TO RELATED APPLICATIONS

This application is based on and claims priority under 35 U.S.C. § 119 to Japanese Patent Application No. 2019-039784, filed on Mar. 5, 2019, the entire content of which is incorporated herein by reference.

### TECHNICAL FIELD

This disclosure relates to a surface acoustic wave filter forming a high-side pass band and a low-side pass band and a design method of the surface acoustic wave filter.

### DESCRIPTION OF THE RELATED ART

As an electronic component constituting various devices, such as a communication device, employs a surface acoustic wave filter as a band-pass filter using resonance of elastic waves, such as a surface acoustic wave (SAW). As this surface acoustic wave filter, a longitudinal mode resonator type filter is known. The longitudinal mode resonator type filter is provided with an input side Inter Digital Transducer (IDT) on a piezoelectric substrate and an output side IDT along a propagation direction of the elastic waves. The longitudinal mode resonator type filter is also provided with a pair of reflectors such that these IDTs are sandwiched from one side and another side in the propagation direction of the elastic waves. For example, Japanese Unexamined Patent Application Publication (Translation of PCT Application) No. 2012-518353 shows the surface acoustic wave filter that is configured to have four DMS tracks as the above-described longitudinal mode resonator type filters formed on a common quartz substrate and have two each of the four DMS tracks connected in parallel.

In order to reduce a count of components that constitute the various devices, one surface acoustic wave filter configured to have a plurality of pass bands has been examined. While details will be described in DETAILED DESCRIPTION of the disclosure, a ripple possibly occurs in a low-side pass band when such a configuration is applied. Thus, this ripple is desired to be suppressed. Note that the surface acoustic wave filter described in the above-described Japanese Unexamined Patent Application Publication (Translation of PCT Application) No. 2012-518353 can be used as a filter that has two pass bands. However, as described above, this surface acoustic wave filter of Japanese Unexamined Patent Application Publication (Translation of PCT Application) No. 2012-518353 includes the four DMS tracks as the longitudinal mode resonator type filters. This increases an area of an electrode formed on a quartz substrate. For example, when the pass band is 300 MHz to 400 MHz, a size of the product increases.

A need thus exists for a surface acoustic wave filter and a design method thereof which are not susceptible to the drawback mentioned above.

### SUMMARY

According to an aspect of this disclosure, there is provided a surface acoustic wave filter that includes a longitudinal mode resonator type first filter portion, a longitudinal mode resonator type second filter portion, an input terminal, and an output terminal. The longitudinal mode resonator type first filter portion arranges an input side IDT electrode and an output side IDT electrode along a propagation direction of an elastic wave on a piezoelectric substrate, and includes a pair of reflectors in a manner sandwiching the IDT electrodes from one side and another side in the propagation direction of the elastic wave to form a high-side pass band. The longitudinal mode resonator type second filter portion arranges an input side IDT electrode and an output side IDT electrode along the propagation direction of the elastic wave on the piezoelectric substrate, and includes a pair of the reflectors in a manner sandwiching the IDT electrodes from the one side and the other side in the propagation direction of the elastic wave to form a low-side pass band in a low side apart from the high-side pass band. The input terminal is commonly connected to the input side IDT electrode of the first filter portion and the input side IDT electrode of the second filter portion. The output terminal is commonly connected to the output side IDT electrode of the first filter portion and the output side IDT electrode of the second filter portion. Assuming a wavelength of a frequency propagating through the first filter portion is defined as k, on the first filter portion, a distance between a center of a width of an electrode finger closest to the output side IDT electrode and a center of a width of an electrode finger closest to the input side IDT electrode is equal to or more than 0.57λ. The electrode finger closest to the output side IDT electrode is closest among electrode fingers that constitute the input side IDT electrode and are arranged in the propagation direction, and the electrode finger closest to the input side IDT electrode is closest among electrode fingers that constitute the output side IDT electrode and are arranged in the propagation direction.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a plan view of a surface acoustic wave filter according to one embodiment disclosed here;

FIG. 2 is a circuit diagram illustrating a matching circuit connected to the surface acoustic wave filter;

FIG. 3 is a graph indicating a pass band property of the surface acoustic wave filter;

FIG. 4 is a graph indicating a pass band property of the surface acoustic wave filter;

FIG. 5 is a graph indicating a pass band property of the surface acoustic wave filter;

FIG. 6 is a graph indicating a pass band property of the surface acoustic wave filter;

FIG. 7 is a graph indicating a pass band property of the surface acoustic wave filter;

FIG. 8 is a graph indicating a pass band property of the surface acoustic wave filter;

FIG. 9 is a graph indicating a pass band property of the surface acoustic wave filter; and

FIG. 10 is a graph indicating a pass band property of the surface acoustic wave filter.

### DETAILED DESCRIPTION

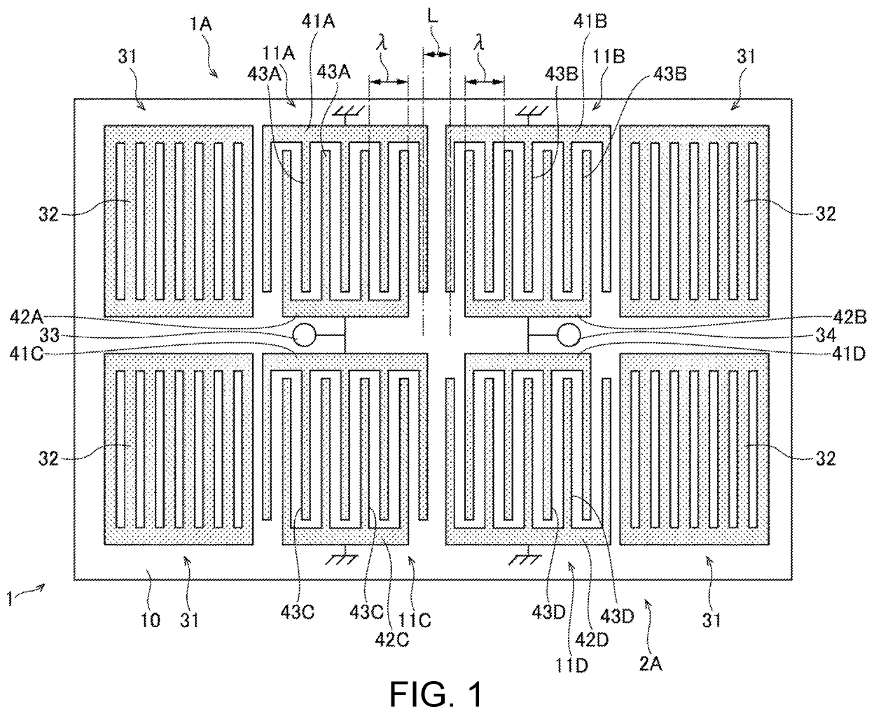

A surface acoustic wave filter 1 as one embodiment disclosed here will be described with reference to a plan view of FIG. 1. This surface acoustic wave filter 1 is configured with two longitudinal mode resonator type filters that are connected in parallel to one another and formed on a quartz substrate 10 as a common piezoelectric substrate. By designing center frequencies of these two longitudinal mode resonator type filters to be shifted one another, the surface acoustic wave filter 1 is configured as a dual filter that has two pass bands close to one another and each having a narrow bandwidth. Each pass band is included in, for example, 300 MHz to 400 MHz. One of the two longitudinal mode resonator type filters and the other are hereinafter referred to as a first filter portion 1A and a second filter portion 2A, respectively.

The first filter portion 1A and the second filter portion 2A form a high-side pass band and a low-side pass band, respectively. The first filter portion 1A and the second filter portion 2A are double mode filters configured such that two resonance points are positioned in each pass band. However, the second filter portion 2A may be configured as a triple mode filter having three resonance points positioned in the pass band. The first filter portion 1A and the second filter portion 2A are arranged side by side in a direction perpendicular to a propagation direction of an elastic wave on the quartz substrate 10. Hereinafter, a description will be given by regarding the propagation direction of the elastic wave as a lateral direction, and an arranging direction of the first filter portion 1A and the second filter portion 2A as a front-back direction.

The first filter portion 1A (second filter portion 2A) includes two IDTs 11A and 11B (11C and 11D) and a pair of reflectors 31. The IDTs 11A and 11B (11C and 11D) are each arranged in line along the propagation direction (lateral direction) of the elastic wave. The pair of reflectors 31 are disposed to sandwich these IDTs 11A and 11B (11C and 11D) from lateral sides. In the drawing, reference sign 32 denotes electrode fingers constituting the reflector 31. Note that the IDTs on an input side disposed on a left side in the lateral direction are 11A and 11C, and the IDTs on an output side disposed on a right side are 11B and 11D. These IDTs 11A to 11D and the reflectors 31 have a thickness of 302 nm in this example and are configured of aluminum.

Each of the IDTs 11A to 11D includes paired busbars 41 and 42 and a plurality of electrode fingers 43. In FIG. 1, these busbars 41 and 42 and the electrode fingers 43 are indicated by being designated with an alphabet identical to an alphabet designated to the IDT 11. Therefore, for the IDT 11A, for example, busbars 41A and 42A, and an electrode finger 43A are used.

A description will be given with an example of this IDT 11A. The busbars 41A and 42A each extend along the propagation direction of the elastic wave and are separate from one another in the front-back direction. The electrode fingers 43A extending from the busbar 41A toward the busbar 42A and the electrode fingers 43A extending from the busbar 42A toward the busbar 41A intersect one another and are alternately arranged as viewed in the lateral direction. The electrode fingers 43 are perpendicular to the busbars 41A and 42A. Since the busbars 41 and 42 and the electrode fingers 43 on the IDTs 11B to 11D are each configured similarly to the busbars 41A and 42A and the electrode fingers 43A on the IDT 11A, its detailed description will be omitted.

On the IDTs 11A to 11D, the electrode fingers 43 are arranged such that a width dimension of the electrode fingers 43 and a separation dimension between the mutually neighboring electrode fingers 43 are periodically repeated along the propagation direction of the elastic wave. An interval of the electrode fingers 43 extending from the busbar 41 (which is also an interval of the electrode fingers 43 extending from the busbar 42) has a period unit, and the elastic wave of a wavelength in this period unit is propagated through the quartz substrate 10. The period unit is individually set for the first filter portion 1A and the second filter portion 2A, and the period unit on the IDTs 11A and 11B constituting the first filter portion 1A is defined as λ.

The busbar 42A and a busbar 41C are connected to an input terminal 33. A busbar 42B and a busbar 41D are connected to an output terminal 34. Accordingly, the input terminal 33 is commonly connected to the IDTs 11A and 11C, and the output terminal 34 is commonly connected to the IDTs 11B and 11D. Additionally, the busbar 41A and busbars 41B, 42C, and 42D are each grounded.

For the first filter portion 1A, an interval between the center of a width of the electrode finger 43 positioned closest to the IDT 11B among the electrode fingers 43 of the IDT 11A and the center of a width of the electrode finger 43 positioned closest to the IDT 11A among the electrode fingers 43 of the IDT 11B is defined as a distance L. Adjusting this distance L causes a property of the surface acoustic wave filter 1 to vary as described in detail later.

The first filter portion 1A is configured such that the respective elastic waves resonate in a region between the IDT 11A and the IDT 11B, inside the IDTs 11A and 11B, and in a region between the reflector 31 on one side and the reflector 31 on the other side, and three different longitudinal modes are excited. Resonance points (resonance frequency) of the elastic waves resonating in the region between the IDT 11A and the IDT 11B, in the inside region of the IDTs 11A and 11B, and in the region between the reflector 31 on the one side and the reflector 31 on the other side constituting the first filter portion 1A are defined as f11, f12, and f13, respectively. The respective resonance points are positioned from the high side toward the low side in this order. The resonance points f11 and f12 are included in the pass band of the first filter portion 1A.

The second filter portion 2A is configured such that the respective elastic waves resonate in a region between the IDT 11C and the IDT 11D, inside the IDTs 11C and 11D, and in a region between the reflector 31 on one side and the reflector 31 on the other side, and three different longitudinal modes are excited. Resonance points (resonance frequency) of the elastic waves resonating in the region between the IDT 11C and the IDT 11D, in the inside region of the IDTs 11C and 11D, and in the region between the reflector 31 on the one side and the reflector 31 on the other side constituting the second filter portion 2A are defined as f21, f22, and f23, respectively. The respective resonance points are positioned from the high side toward the low side in this order. Accordingly, the pass band of the second filter portion 2A includes f21 and f22 as the first resonance point and the second resonance point.

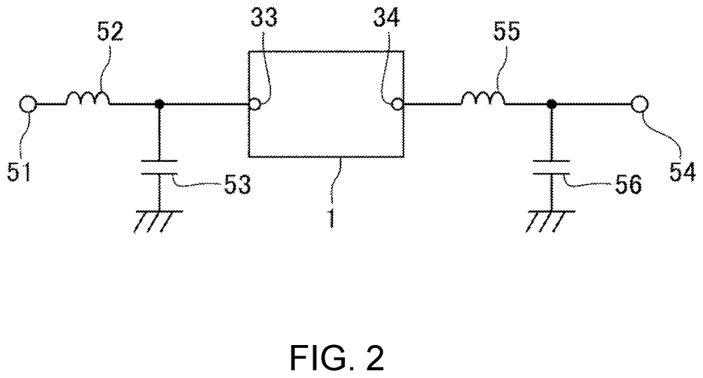

FIG. 2 illustrates a state of matching by installing a matching circuit in the surface acoustic wave filter 1. In the drawing, reference sign 51 denotes an input terminal of the matching circuit, and the input terminal 51 is connected to the input terminal 33 of the surface acoustic wave filter 1. Between the terminals 51 and 33, an inductor 52 that is connected in series, and a capacitor 53 that is connected in parallel and is grounded are disposed toward a latter part in this order. In the drawing, reference sign 54 denotes an output terminal of the matching circuit, and the output terminal 54 is connected to the output terminal 34 of the surface acoustic wave filter 1. Between the terminals 54 and 34, an inductor 55 that is connected in series, and a capacitor 56 that is connected in parallel and is grounded are disposed toward a latter part in this order. Installing such a matching circuit adjusts an impedance at the latter part of the output terminal 54 to be 50Ω.

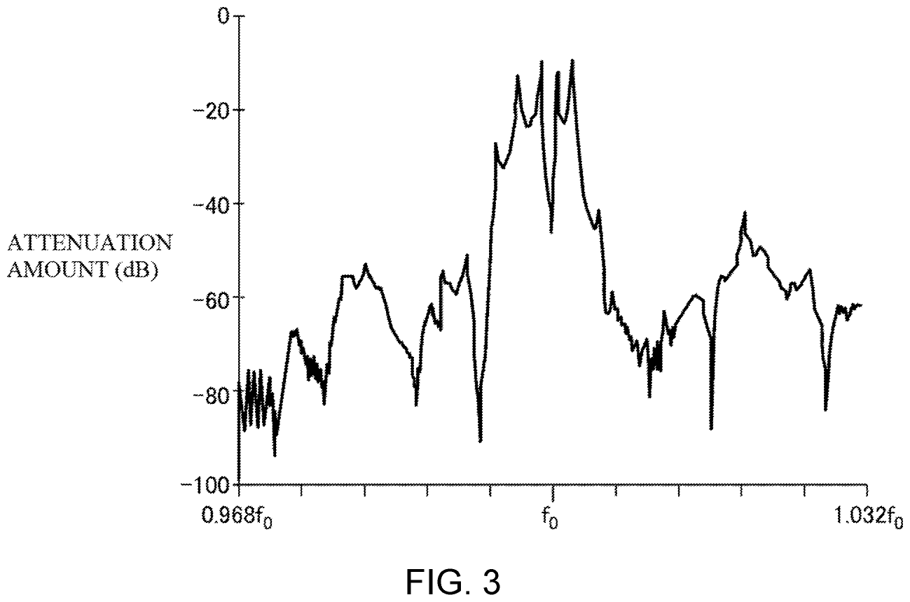

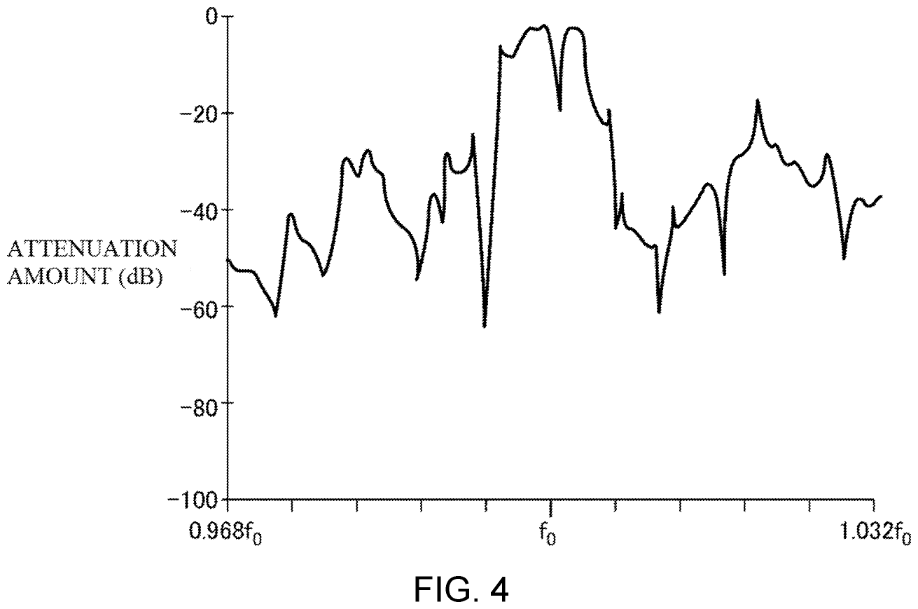

FIG. 3 and FIG. 4 indicate the properties of the surface acoustic wave filter 1 with the distance L=0.58λ described in FIG. 1. Note that graphs of these FIG. 3, FIG. 4, and the respective drawings indicating filter properties described later each have a frequency (unit: Hz) on a horizontal axis and an attenuation amount (unit: dB) on a vertical axis. FIG. 3 indicates the filter property obtained in a state without matching, that is, without installing the matching circuit described in FIG. 2, but with the surface acoustic wave filter 1 indicated in FIG. 1 alone. FIG. 4 indicates the filter property obtained in a state with matching, that is, with the above-described matching circuit installed. The surface acoustic wave filter 1 whose properties are indicated in these FIG. 3 and FIG. 4 has a center frequency f0 of 315 MHz band and a span width of 20 MHz. Additionally, for 3 dB bandwidth, the low side is 1000 kHz (fractional bandwidth 0.32%), and the high side is 600 kHz (fractional bandwidth 0.19%). A frequency difference between the low side and the high side is 1.15 MHz.

Incidentally, since this surface acoustic wave filter 1 forms two neighboring pass bands as described above, the lowest-side resonance point (third resonance point) f13 among the resonance points of the above-described first filter portion 1A is included in the pass band of the second filter portion 2A. The respective resonance points are positioned from the high side toward the low side in the order of f21, f13, and f22. Since f13 is included in the pass band of the second filter portion 2A that way, a ripple occurs in the pass band of the second filter portion 2A when a level of the resonance of this f13 is large.

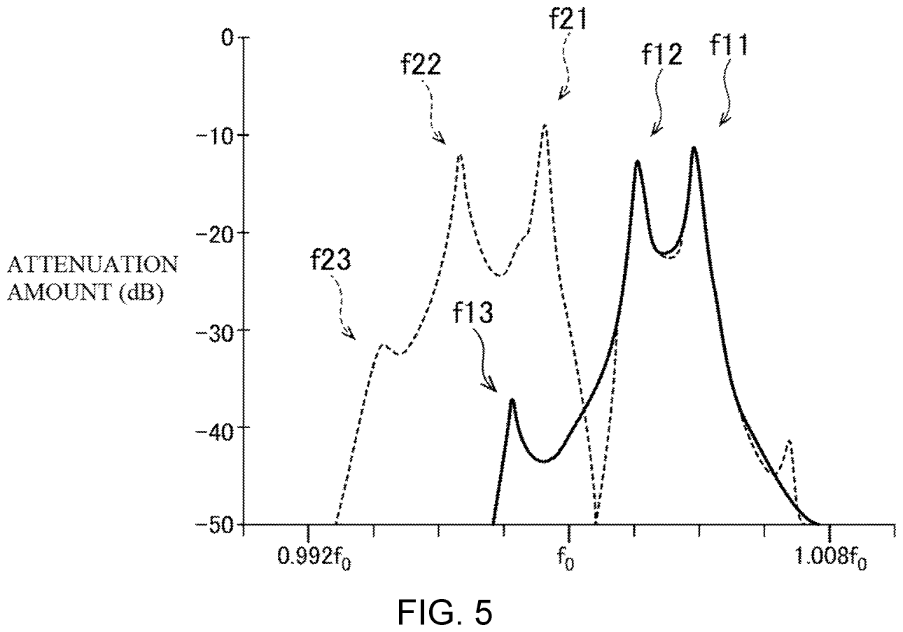

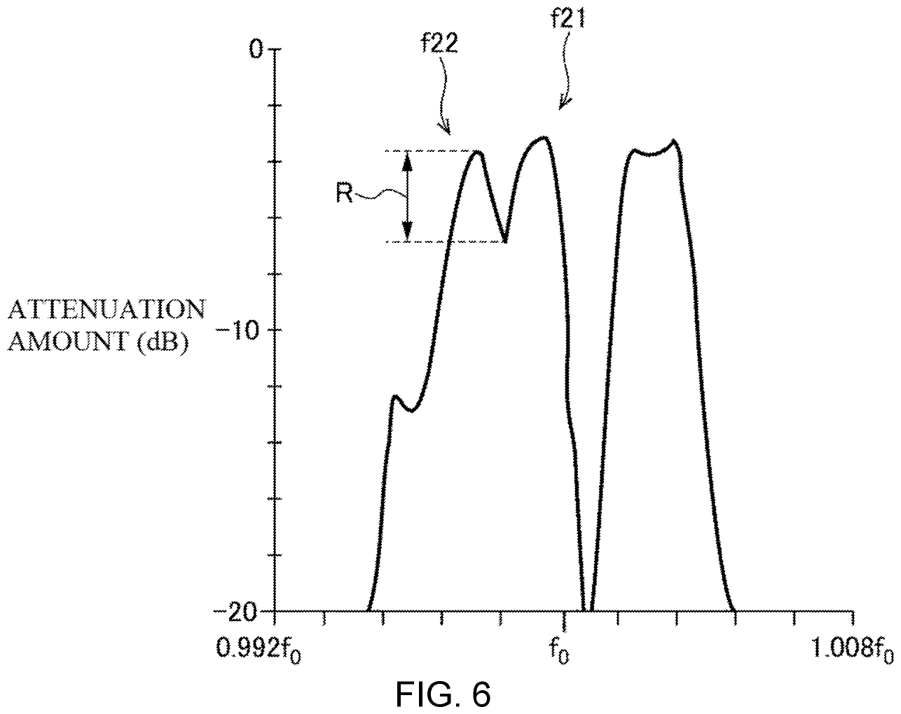

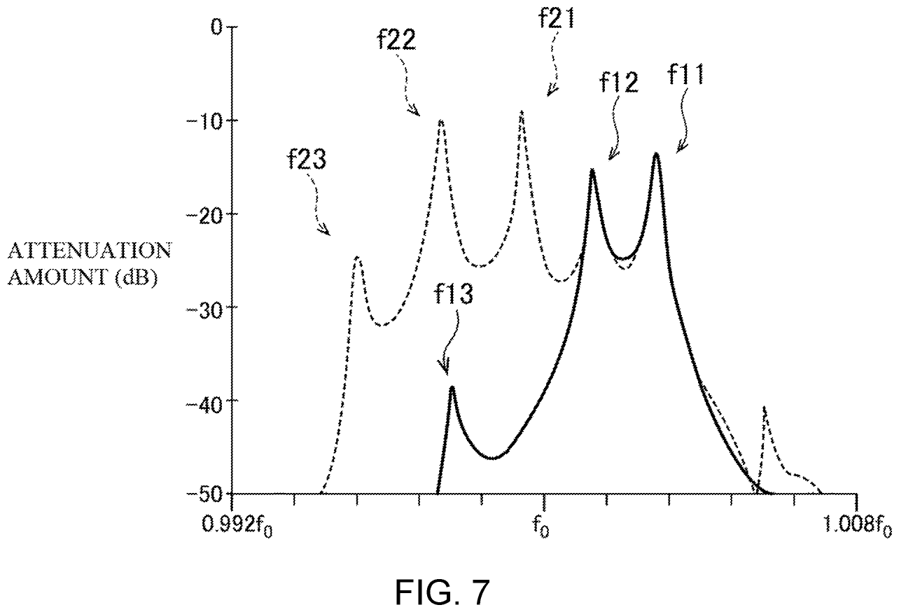

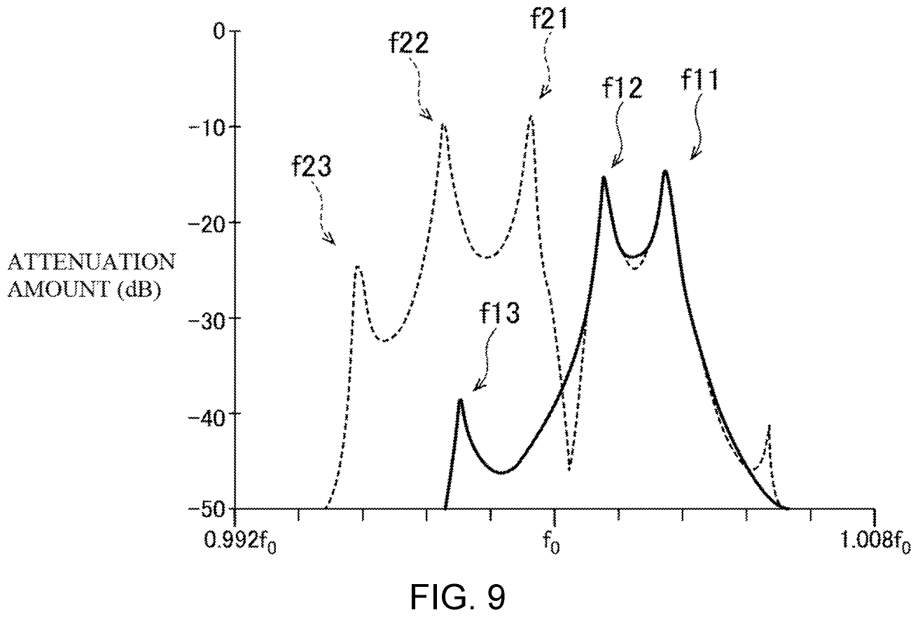

(Comparative Example) The following describes an example where the ripple occurs that way. Similarly to FIG. 3 and FIG. 4, FIG. 5 and FIG. 6 respectively indicate the filter property obtained without matching and the filter property obtained with matching, respectively. However, the properties in FIG. 5 and FIG. 6 are obtained from the surface acoustic wave filter 1 with the distance L=0.56λ, and this surface acoustic wave filter 1 is defined as the surface acoustic wave filter 1 of Comparative Example. Note that in this FIG. 5 and FIG. 7, FIG. 9 described later, the properties of the first filter portion 1A and the properties of the second filter portion 2A are indicated in a solid line and in a dotted line, respectively.

As indicated in FIG. 5, the surface acoustic wave filter 1 of Comparative Example has a relatively large f13 level that is −37 dB, and it is seen that a waveform strain appears in the pass band of the second filter portion 2A. Even in a state with matching as indicated in FIG. 6, a ripple R becomes to have a relatively large value that is equal to or more than 2 dB compared with the resonance point f22.

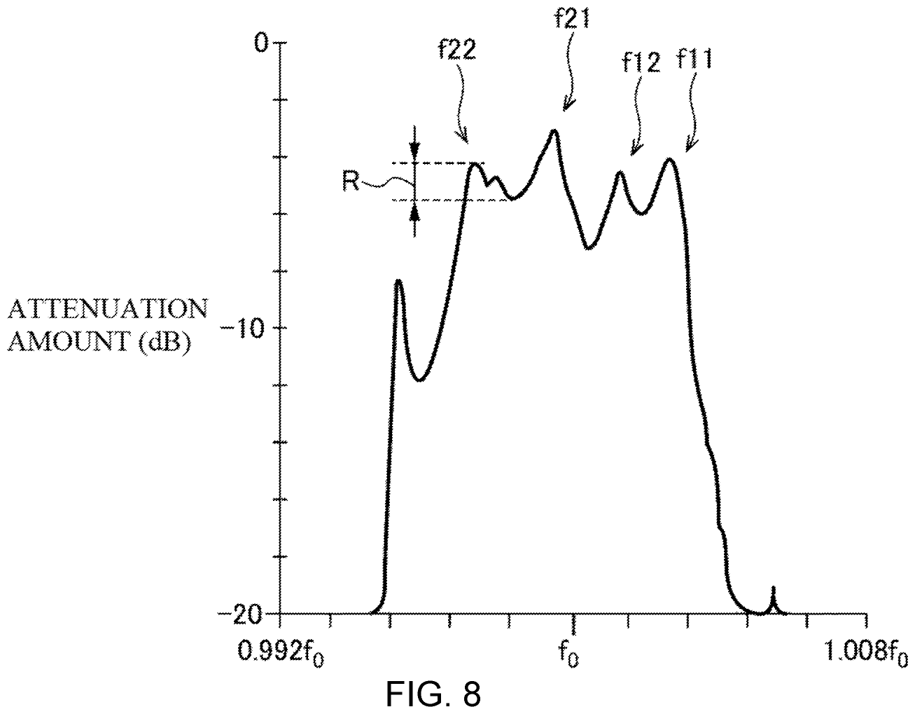

(Working Example 1) Similarly to FIG. 3 and FIG. 4, FIG. 7 and FIG. 8 respectively indicate the filter property obtained without matching and the filter property obtained with matching, respectively. However, the properties in FIG. 7 and FIG. 8 are obtained from the surface acoustic wave filter 1 with the distance L=0.57λ, and this surface acoustic wave filter 1 is defined as the surface acoustic wave filter 1 of Working Example 1. In the surface acoustic wave filter 1 of Working Example 1 indicated in FIG. 7, a level of the resonance point f13 is −38 dB and lower than the level of the resonance point f13 in the surface acoustic wave filter 1 of Comparative Example indicated in FIG. 5. Then, comparing between the surface acoustic wave filter 1 of Working Example 1 and the surface acoustic wave filter 1 of Comparative Example on the ripple R in a state with matching, the ripple R of the surface acoustic wave filter 1 of Working Example 1 is more suppressed. According to FIG. 8, the ripple R of the surface acoustic wave filter 1 of Working Example 1 is depressed by around 0.8 dB compared with the resonance point f22 that has a lower level of the resonance between the resonance point f21 and the resonance point f22. When this ripple R (spike-like spurious response) occurs in the pass band of the second filter portion 2A, the ripple R is preferably suppressed to equal to or less than 1 dB. Therefore, the ripple R is suppressed to a preferred value in this Working Example 1.

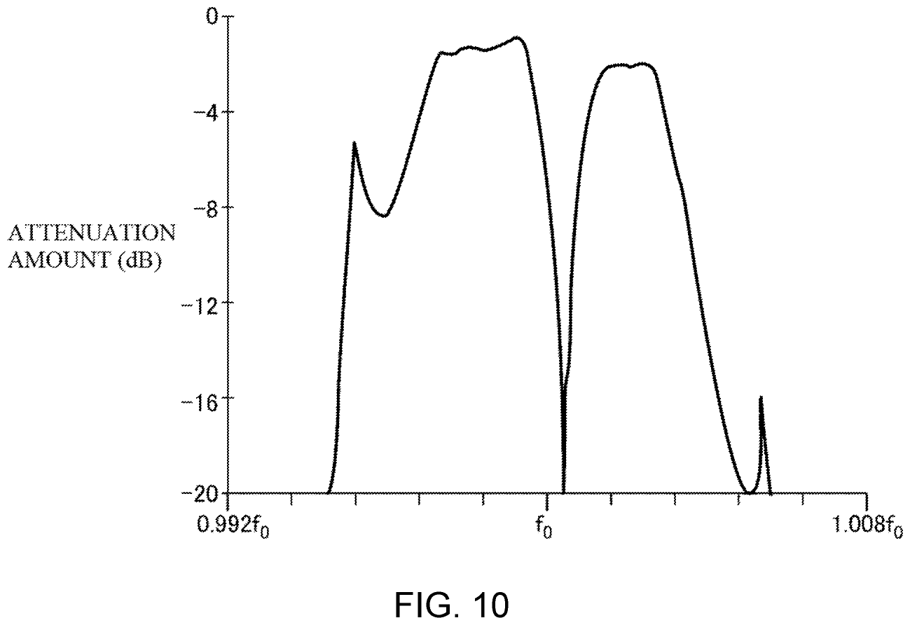

(Working Example 2) Similarly to FIG. 3 and FIG. 4, FIG. 9 and FIG. 10 respectively indicate the filter property obtained without matching and the filter property obtained with matching, respectively. However, the properties in FIG. 9 and FIG. 10 are obtained from the surface acoustic wave filter 1 with the distance L=0.58λ, and this surface acoustic wave filter 1 is defined as the surface acoustic wave filter 1 of Working Example 2. In the surface acoustic wave filter 1 of Working Example 2 indicated in FIG. 9, a level of the resonance point f13 is slightly lower than −38 dB, that is, the level is more suppressed than the level of the resonance point f13 of the surface acoustic wave filter 1 of Working Example 1. Then, the ripple R in a state with matching in the surface acoustic wave filter 1 of Working Example 2 is approximately 0 dB as indicated in FIG. 10. Note that the surface acoustic wave filter 1 whose properties are indicated in the above-described FIG. 3 and FIG. 4 has adjusted parameters of the surface acoustic wave filter 1 from which the properties indicated in FIG. 9 and FIG. 10 are obtained, except for the distance L. Therefore, the surface acoustic wave filter 1 whose properties are indicated in FIG. 3 and FIG. 4 and the surface acoustic wave filter 1 of Working Example 2 whose properties are indicated in FIG. 9 and FIG. 10 have the same setting about the distance L, but the properties indicated in FIG. 3 and FIG. 4 and the properties indicated in FIG. 9 and FIG. 10 are slightly different.

As can be seen from the above-described Comparative Example and Working Example 1 and 2, it is confirmed that the level of the resonance point f13 can be suppressed with increase in the above-described distance L, which suppresses the ripple R that occurs in the pass band by the second filter portion 2A and can make the property of the pass band satisfactory. Then, since the ripple R is sufficiently suppressed for practical use in the surface acoustic wave filter 1 of Working Example 1, the distance L is set to equal to or more than 0.57λ. From the properties of the surface acoustic wave filter 1 of Working Example 2, the distance L is preferably equal to or more than 0.58λ.

Note that the embodiment disclosed this time is illustrative in every point and should be considered not to be restrictive. The above-described embodiment may be omitted, replaced, and changed in various manners without departing from accompanying claims and their spirits.

According to the disclosure, on the first filter portion, the distance between the center of the width of the electrode finger closest to the output side IDT electrode and the center of the width of the electrode finger closest to the input side IDT electrode is set to equal to or more than 0.57λ. The electrode finger closest to the output side IDT electrode is closest among the electrode fingers that constitute the input side IDT electrode and are arranged in the propagation direction of the elastic wave. The electrode finger closest to the input side IDT electrode is closest among the electrode fingers that constitute the output side IDT electrode and are arranged in the propagation direction of the elastic wave. With such a configuration, the ripple caused by the resonance in the first filter portion can be suppressed in the low-side pass band formed by the second filter portion, and thus the property of the low-side pass band is made satisfactory.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A surface acoustic wave filter comprising:
a longitudinal mode resonator type first filter portion that arranges an input side IDT electrode and an output side IDT electrode along a propagation direction of an elastic wave on a piezoelectric substrate, and includes a pair of reflectors in a manner sandwiching the IDT electrodes from one side and another side in the propagation direction of the elastic wave to form a high-side pass band;
a longitudinal mode resonator type second filter portion that arranges an input side IDT electrode and an output side IDT electrode along the propagation direction of the elastic wave on the piezoelectric substrate, and includes a pair of the reflectors in a manner sandwiching the IDT electrodes from the one side and the other side in the propagation direction of the elastic wave to form a low-side pass band in a low side apart from the high-side pass band;
an input terminal commonly connected to the input side IDT electrode of the first filter portion and the input side IDT electrode of the second filter portion; and
an output terminal commonly connected to the output side IDT electrode of the first filter portion and the output side IDT electrode of the second filter portion, wherein
assuming a wavelength of a frequency propagating through the first filter portion is defined as λ, on the first filter portion, a distance between a center of a width of an electrode finger closest to the output side IDT electrode and a center of a width of an electrode finger closest to the input side IDT electrode is equal to or more than 0.57λ, the electrode finger closest to the output side IDT electrode being closest among electrode fingers that constitute the input side IDT electrode and are arranged in the propagation direction, and the electrode finger closest to the input side IDT electrode being closest among electrode fingers that constitute the output side IDT electrode and are arranged in the propagation direction.

2. The surface acoustic wave filter according to claim 1, wherein
the first filter portion is a double mode filter where a first resonance point and a second resonance point by the first filter portion are each positioned in the high-side pass band, and a third resonance point by the first filter portion is positioned in the low-side pass band.

3. The surface acoustic wave filter according to claim 1, wherein
the distance is equal to or more than 0.58λ.

4. A method for designing a surface acoustic wave filter, wherein
the surface acoustic wave filter includes a longitudinal mode resonator type first filter portion that arranges an input side IDT electrode and an output side IDT electrode along a propagation direction of an elastic wave on a piezoelectric substrate, and includes a pair of reflectors in a manner sandwiching the IDT electrodes from one side and another side in the propagation direction of the elastic wave to form a high-side pass band;
a longitudinal mode resonator type second filter portion that arranges an input side IDT electrode and an output side IDT electrode along the propagation direction of the elastic wave on the piezoelectric substrate, and includes a pair of the reflectors in a manner sandwiching the IDT electrodes from the one side and the other side in the propagation direction of the elastic wave to form a low-side pass band in a low side apart from the high-side pass band;
an input terminal commonly connected to the input side IDT electrode of the first filter portion and the input side IDT electrode of the second filter portion; and
an output terminal commonly connected to the output side IDT electrode of the first filter portion and the output side IDT electrode of the second filter portion, wherein
the method comprising:
designing the first filter portion as a double mode filter where a first resonance point and a second resonance point by the first filter portion are each positioned in the high-side pass band;
positioning a third resonance point by the first filter portion in the low-side pass band; and
designing a ripple in the low-side pass band to be equal to or less than 1 dB compared with a resonance point that has a lowest level resonance among the resonance points on the second filter portion included in the low-side pass band.
